(19) United States
(12) Patent Application Publication
(10) Pub. No.: US 2021/0356216 A1
(43) Pub. Date: Nov. 18, 2021

(54) ENHANCED HEAT CONDUCTION COMPONENTS

(71) Applicant: CONCEPT GROUP LLC, Wellesley, MA (US)

(72) Inventors: Shriram RADHAKRISHNAN, West Palm Beach, FL (US); David H. REID, JR., Fort Pierce, FL (US); Aarne H. REID, Jupiter, FL (US); Peter ROACH, Jacksonville, FL (US); Lucas PYE, West Palm Beach, FL (US)

(21) Appl. No.: 17/296,346

(22) PCT Filed: Nov. 26, 2019
(86) PCT No.: PCT/US2019/063207

§ 371 Date: May 24, 2021

Related U.S. Application Data
(60) Provisional application No. 62/771,354, filed on Nov. 26, 2018.

(51) Int. Cl. F28D 15/04; F28F 13/14

(52) U.S. Cl. CPC F28D 15/046; F28F 13/14

(57) ABSTRACT

Provided are heat transfer components that include a wick and a working fluid enclosed within a sealed evacuated space. Also provided are related methods of using the components.

### RELATED APPLICATIONS

The present application claims priority to and the benefit of U.S. Application No. 62/771,354, “Enhanced Heat Conduction Components” (filed Nov. 26, 2018), the entirety of which application is incorporated herein by reference for any and all purposes.

### TECHNICAL FIELD

The present disclosure relates to the field of heat transfer components, in particular the field of heat pipes.

### BACKGROUND

Because the heat generated by electronic components can be significant and can impair the components' performance, it has been recognized that it is necessary to transport that heat away from the heat-generating component. Existing methods of doing so, are limited in their capabilities, which in turn imposes design constraints on electronic products, as the products cannot include components that generate more heat than can be removed by existing heat transfer components. Accordingly, there is a long-felt need in the art for heat transfer components that feature enhanced performance.

### SUMMARY

In meeting the described long-felt needs, the present disclosure provides heat transfer components, comprising: a sealed enclosure, the sealed enclosure having within a cavity having a first part, a second part, and a third part, the first part of the cavity being configured to receive heat from a heat source and the third part of the cavity being configured to deliver heat received from the heat source; a fluid disposed within the cavity; a wick disposed within the enclosure, the wick being in fluid communication with the fluid and also with at least the first part of the cavity and the third part of the cavity of the cavity, and the wick being capable of transporting fluid (a) between the first part of the cavity and the third part of the cavity, (b) between the third part of the cavity and the first part of the cavity, or both (a) and (b); and a first sealed evacuated space defined between two walls disposed between the second part of the cavity and the environment exterior to the heat transfer component.

Also provided are methods, comprising: with a heat transfer component according to the present disclosure, transferring with the heat transfer component heat that is received from a heat source.

Further provided are methods, comprising with a heat transfer component according to the present disclosure, exposing the heat component to heat from a heat source so as to vaporize fluid within the first part of the cavity, to effect condensation of the fluid within the third part of the cavity, and to effect transport of the condensed fluid along the wick from the third part of the cavity to the first part of the cavity.

Additionally provided are heat transfer components, comprising: a tubular enclosure, the tubular enclosure having within a sealed annular cavity, the sealed annular cavity having a first part, a second part, and a third part; a fluid disposed within the sealed annular cavity; and a wick disposed within the sealed annular cavity, the wick being in fluid communication with the fluid and the wick being capable of transporting fluid (a) between the first part of the cavity and the third part of the cavity, (b) between the third part of the cavity and the second part of the cavity, or both (a) and (b); and a first sealed evacuated space disposed between the second part of the cavity and the environment exterior to the heat transfer component.

Further provided are methods, comprising: with a heat transfer component according to the present disclosure, transferring with the heat transfer component heat that is received from a heat source.

Also disclosed are methods, comprising with a heat transfer component according to the present disclosure, exposing the heat component to heat from a heat source so as to vaporize fluid within the first part of the cavity, to effect condensation of the fluid within the third part of the cavity, and to effect transport of the condensed fluid along the wick from the third part of the cavity to the first part of the cavity.

### BRIEF DESCRIPTION OF THE DRAWINGS

In the drawings, which are not necessarily drawn to scale, like numerals may describe similar components in different views. Like numerals having different letter suffixes may represent different instances of similar components. The drawings illustrate generally, by way of example, but not by way of limitation, various aspects discussed in the present document. In the drawings:

FIG. 1A provides a view of an exemplary heat transfer component according to the present disclosure;

FIG. 1B provides a close up view of a portion of an exemplary heat transfer component according to the present disclosure;

FIG. 1C provides a close up view of a portion of an exemplary heat transfer component according to the present disclosure;

FIG. 2A provides a view of an exemplary heat transfer component according to the present disclosure;

FIG. 2B provides a close up view of a portion of an exemplary heat transfer component according to the present disclosure;

FIG. 2C provides a close up view of a portion of an exemplary heat transfer component according to the present disclosure;

FIG. 3A provides a view of an exemplary heat transfer component according to the present disclosure;

FIG. 3B provides a close up view of a portion of an exemplary heat transfer component according to the present disclosure;

FIG. 4A provides a view of an exemplary heat transfer component according to the present disclosure;

FIG. 4B provides a close up view of a portion of an exemplary heat transfer component according to the present disclosure;

FIG. 4C provides a close up view of a portion of an exemplary heat transfer component according to the present disclosure;

FIG. 5A provides a view of an exemplary heat transfer component according to the present disclosure;

FIG. 5B provides a close up view of a portion of an exemplary heat transfer component according to the present disclosure;

FIG. 6A provides a cutaway view of a portion of an exemplary heat transfer component according to the present disclosure;

FIG. 6B provides a cutaway view of a portion of an exemplary heat transfer component according to the present disclosure;

FIG. 6C provides a cutaway view of a portion of an exemplary heat transfer component according to the present disclosure;

FIG. 6D provides a cutaway view of a portion of an exemplary heat transfer component according to the present disclosure;

FIG. 7 provides an end-on view of an exemplary heat transfer component according to the present disclosure;

FIG. 8 provides a cutaway view of an exemplary heat transfer component according to the present disclosure;

FIG. 9 provides a cutaway view of a portion of an exemplary heat transfer component according to the present disclosure; and

FIG. 10 provides a cutaway view of a portion of an exemplary heat transfer component according to the present disclosure.

### DETAILED DESCRIPTION OF ILLUSTRATIVE EMBODIMENTS

The present disclosure may be understood more readily by reference to the following detailed description taken in connection with the accompanying figures and examples, which form a part of this disclosure. It is to be understood that this invention is not limited to the specific devices, methods, applications, conditions or parameters described and/or shown herein, and that the terminology used herein is for the purpose of describing particular embodiments by way of example only and is not intended to be limiting of the claimed invention.

Also, as used in the specification including the appended claims, the singular forms “a,” “an,” and “the” include the plural, and reference to a particular numerical value includes at least that particular value, unless the context clearly dictates otherwise. The term “plurality”, as used herein, means more than one. When a range of values is expressed, another embodiment includes from the one particular value and/or to the other particular value. Similarly, when values are expressed as approximations, by use of the antecedent “about,” it will be understood that the particular value forms another embodiment. All ranges are inclusive and combinable, and it should be understood that steps may be performed in any order.

It is to be appreciated that certain features of the invention which are, for clarity, described herein in the context of separate embodiments, may also be provided in combination in a single embodiment. Conversely, various features of the invention that are, for brevity, described in the context of a single embodiment, may also be provided separately or in any subcombination. All documents cited herein are incorporated herein in their entireties for any and all purposes.

Further, reference to values stated in ranges include each and every value within that range. In addition, the term “comprising” should be understood as having its standard, open-ended meaning, but also as encompassing “consisting” as well. For example, a device that comprises Part A and Part B may include parts in addition to Part A and Part B, but may also be formed only from Part A and Part B.

Figures

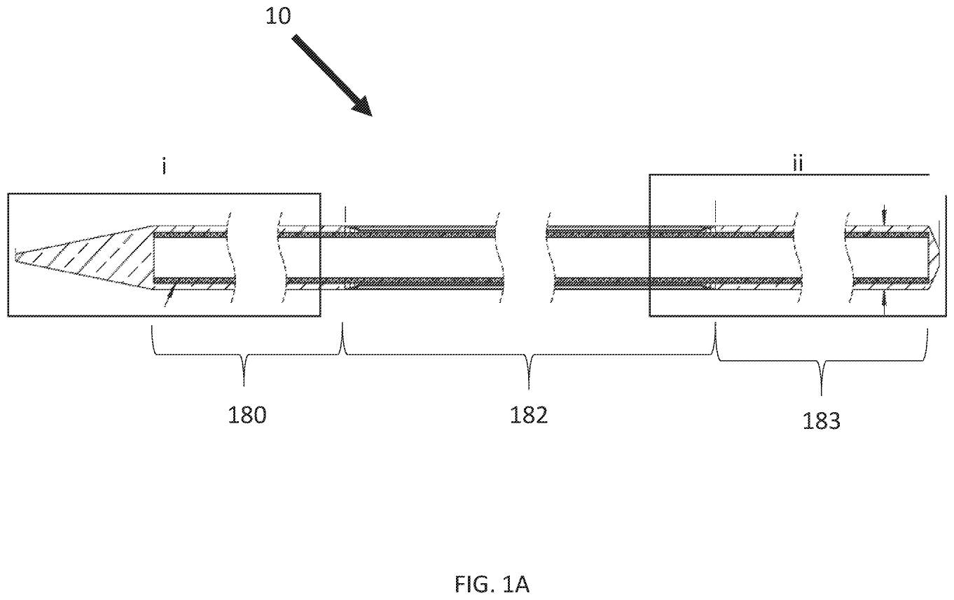

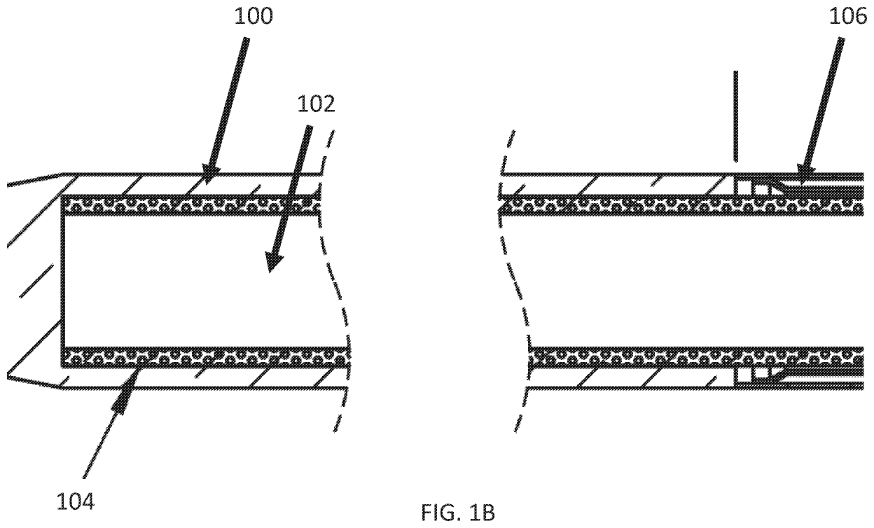

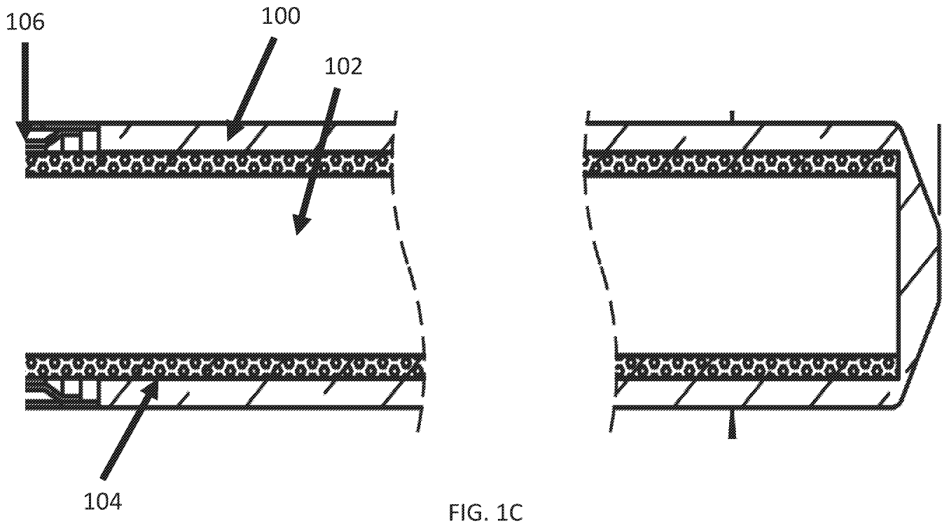

The attached non-limiting figures illustrate certain aspects of the disclosed technology. FIG. 1A provides a depiction of a component 10. As shown, the component includes a cavity within that in turn includes a first part 180, a second part 182, and a third part 183. As shown, the component can have a flat or rounded end, but can also have a pointed or tapered end (shown, but not labeled.)

FIG. 1B provides a closer view of the boxed region (i) in FIG. 1A. As shown, component 10 can include an outer wall 100, which can be termed an enclosure in certain embodiments. The outer wall 100 can enclose a cavity 102 therein, as well as a fluid (not shown) contained within cavity 102. The enclosure can also enclose wick 104, which wick can operate to provide a substrate onto which vapor condenses and also to transport, e.g., via capillary action, fluid that has condensed onto the wick. A sealed evacuated space 106 can enclose at least a portion of wick 104. Wick 104 can be present in tubular form, although this is not a requirement. FIG. 1C provides a closer view of area (ii) boxed in FIG. 1A. As shown, sealed evacuated space 106 encloses at least a portion of wick 104.

Without being bound to any particular theory, a heat transfer component can operate by utilizing thermal conductivity and phase transition to effectively transfer heat between two solid interfaces. At the hot interface of a heat pipe a liquid in contact with a thermally conductive solid surface turns into a vapor by absorbing heat from that surface. The vapor then travels along the heat pipe to the cold interface and condenses back into a liquid—releasing the latent heat. The liquid then returns to the hot interface through either capillary action, centrifugal force, or gravity, and the cycle repeats. Without being bound to any particular theory, the capillary action can transport fluid (e.g., liquid) against a pressure gradient that may exist within the heat pipe.

By reference to FIG. 1A, 1B, and 1C, component 10 can absorb heat from a heat source, e.g., a computer processor. Fluid contained in the first part 180 of component 10 can vaporize, and is communicated within cavity 102 along second part 182 to third part 183. At third part 183, the fluid condenses onto wick located in third part 183. Fluid that condenses onto wick 104 is then communicated along the wick, e.g., via capillary action, along second part 182 back to first part 180. At that location, heat absorbed by the component then vaporizes the fluid, and the cycle is repeated. Without being bound by any particular theory, vapor transport within the cavity is enhanced by the relatively higher pressure in the part of the cavity where the fluid is vaporized to vapor form, which relatively higher pressure can act to encourage the vapor's transport within the cavity to the third part of the cavity (where the vapor condenses onto the wick), where the pressure is comparatively lower. Also without being bound to any particular theory, the capillary action can transport fluid (e.g., liquid) against a pressure gradient that may exist within the cavity of the heat transfer component.

As shown in FIG. 1A, 1B, and 1C, sealed evacuated space 106 acts to provide additional insulation to at least a portion of wick 104 and cavity 102. This additional thermal insulation improves the overall thermal transfer performance of the component. In some embodiments, an end of the component end can terminate at a heat sink or even be attached directly to the heat source.

Without being bound to any particular theory or embodiment, a wall (e.g., wall 100) of a component can flare outwards. As one example, one or both walls of the assembly can flare outwards (in a bell-like geometry) at an end of the assembly that acts ast the “hot end” of the component, i.e., the region of the component where the working fluid is vaporized by heat absorbed by the component. Again without being bound to any particular theory, such a flared/expanding geometry can promote expansion and cause additional cooling, e.g., via the Joule-Thomson effect.

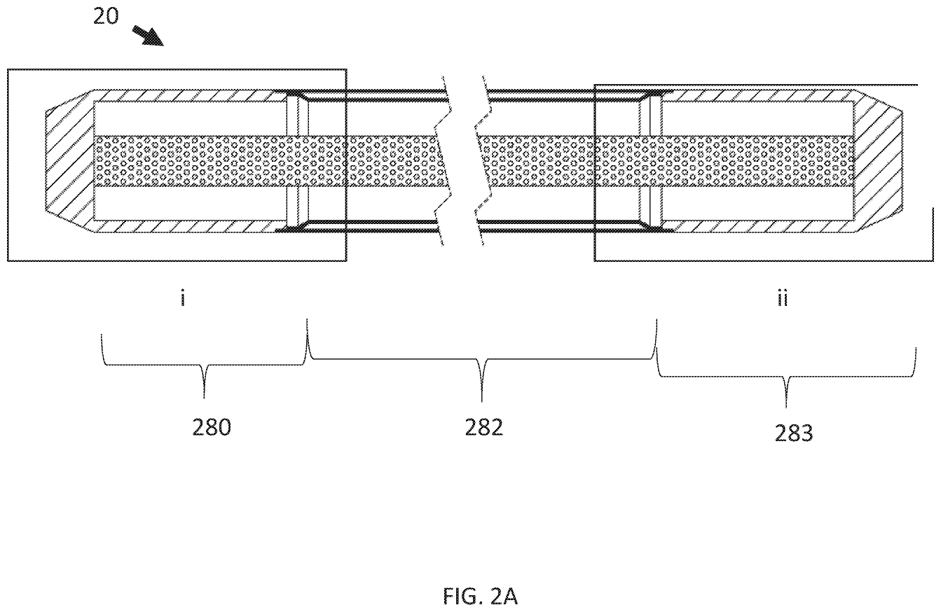

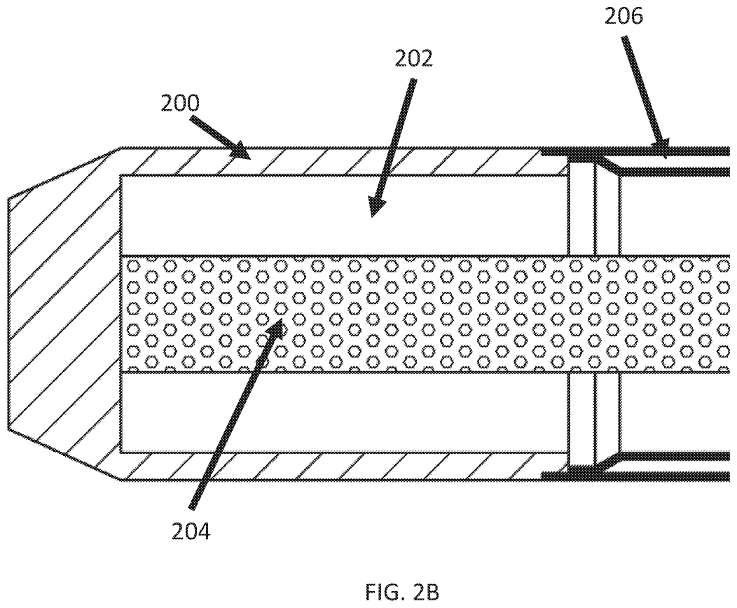

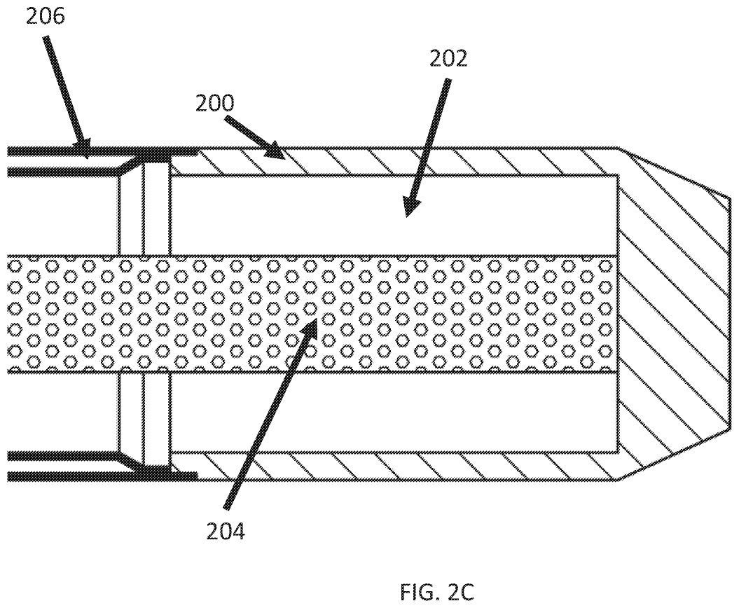

FIG. 2A provides an alternative embodiment of the disclosed technology. As shown, the component includes a cavity within that in turn includes a first part 280, a second part 282, and a third part 283. As shown, the component can have a flat or rounded end, but can also have a pointed or tapered end.

FIG. 2B provides a closer view of the boxed region (i) in FIG. 2A. As shown, component 20 can include an outer wall 200, which can be termed an enclosure in certain embodiments. The outer wall 200 can enclose a cavity 202 therein, as well as a fluid (not shown) contained within cavity 202. The enclosure can also enclose wick 204, which wick can operate to provide a substrate onto which vapor condenses and also to transport, e.g., via capillary action, fluid that has condensed onto the wick. A sealed evacuated space 206 can enclose at least a portion of wick 204. Wick 204 can be present in columnar form, although this is not a requirement. FIG. 2C provides a closer view of area (ii) boxed in FIG. 2A. As shown, sealed evacuated space 206 encloses at least a portion of wick 204.

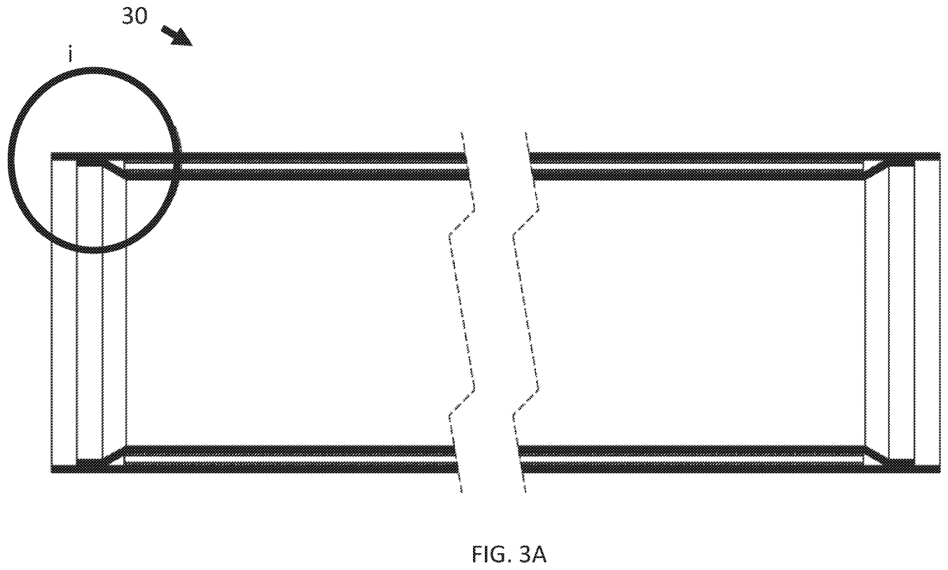

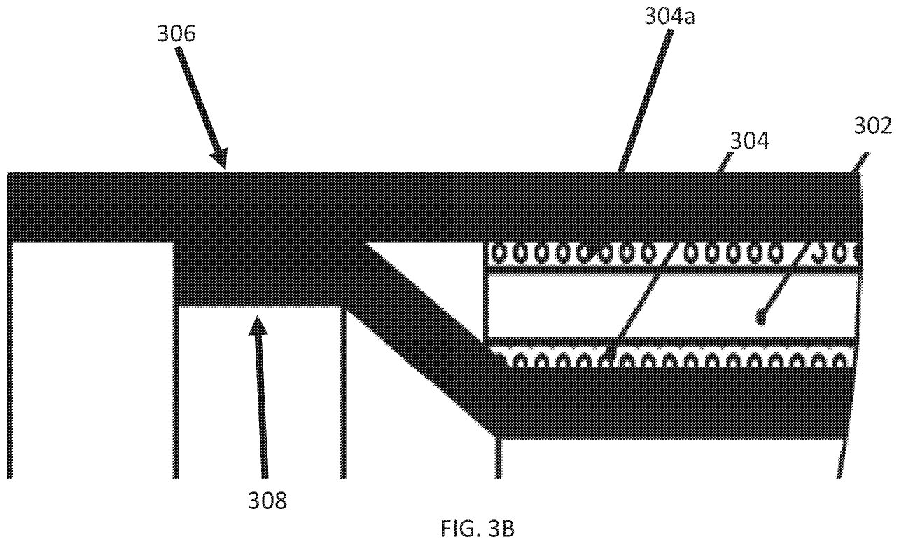

FIG. 3A provides a further alternative embodiment of a component 30 according to the disclosed technology. FIG. 3B provides a close up view of the region (i) circled in FIG. 3A. As shown in FIG. 3B, a cavity 302 can be defined between first wall 306 and second wall 308. As shown, one or both of the first and second walls can taper and/or flare toward the other, although this is not a requirement. Cavity 302 can be at ambient pressure, but can also be at reduced (sub-ambient) pressure, or even at increased (above ambient) pressure. Wick 304a can be disposed within cavity 302. A fluid (not shown) can be disposed within cavity 304. In some embodiments, wick portion 304 can also be present. It is not a requirement, however, that wick material be present in two portions. Wick material can be present in tubular form, but this is not a requirement, as wick material can be present as strips, stripes, or in other shapes.

Without being bound in any particular theory, fluid that vaporizes (from heat absorption) within a part of cavity 302 is transported, as vapor, within cavity 304 to a location where the vapor condenses onto wick material. Following that condensation, the condensed fluid is transported, e.g., via capillary action, along the wick back to the portion of the component where the fluid is then vaporized by heat absorbed by the component, as described elsewhere herein.

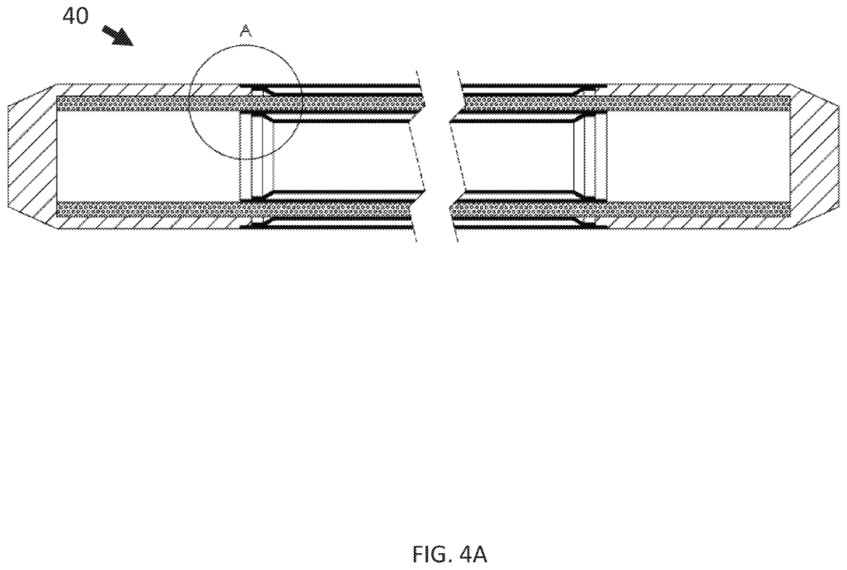

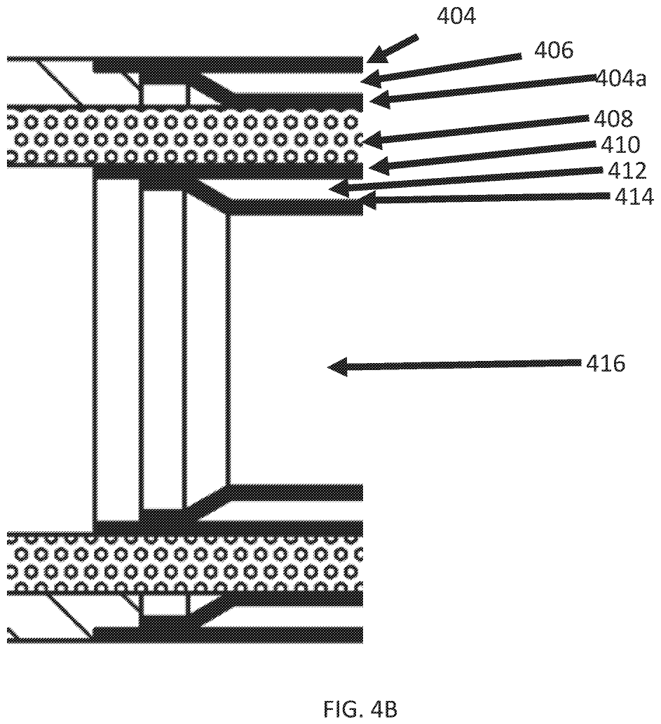

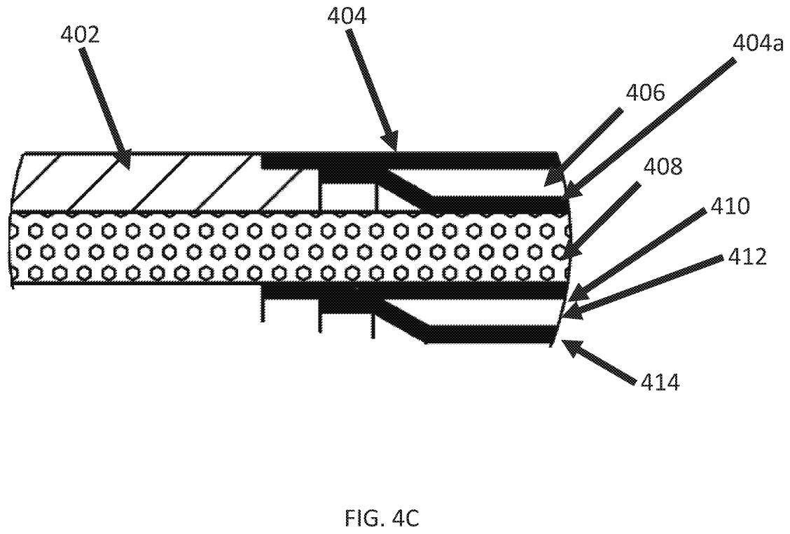

FIG. 4A provides a view of a component 40 according to the present disclosure. Although not shown, the component can include a first part where heat is absorbed by the component and fluid within the component is vaporized, a second part through which vaporized fluid is transported, and a third part where vaporized fluid condenses.

FIG. 4B provide a close up view of the boxed area in FIG. 4A. As shown, the component can include a space 406, through which vaporized fluid can travel, e.g., fluid that has vaporized as a result of heat absorbed by the component. The cavity can be enclosed by a first sealed, evacuated space 406, which can be defined between walls 404 and 404a. Wick 408 can operate to transport fluid that has condensed as vapor on one part of the wick. As one example, fluid can be vaporized (by heat absorbed by the component), which vapor is transported within cavity 416. The vapor can then condense on a portion of wick 408, after which the condensed vapor is transported along wick (e.g., via capillary action) back to a part of the component where the condensed vapor is vaporized again by heat absorbed by the component. Cavity 416 can also be enclosed by a second sealed evacuated space 412, which can be defined between walls 410 and 414.

Some exemplary sealed spaces (and related techniques for forming and using such structures) can be found in published United patent applications 2017/0253416; 2017/0225276; 2017/0120362; 2017/0062774; 2017/0043938; 2016/0084425; 2015/0260332; 2015/0110548; 2014/0090737; 2012/0090817; 2011/0264084; 2008/0121642; and 2005/0211711, as well as in PCT/US2019/027682. All of the foregoing documents (and any priority documents mentioned therein) are incorporated herein by reference in their entireties for any and all purposes. The pressure in a sealed space can be from, e.g., 1 to 10⁻⁹ Torr, or from 10⁻¹ to 10⁻⁸ Torr, or from 10⁻² to 10⁻⁷ Torr, or from 10⁻³ to 10⁻⁶ Torr, or even from 10⁻⁴ to 10⁻⁵ Torr.

A further close-up view of the component of FIG. 4B is shown in FIG. 4C. As shown, the component can include a wall 402 that is joined to walls 404 and 404a that define sealed evacuated space 406. As shown, wick 408 can run along a portion of the length of component 40, including along a portion of evacuated spaces 406 and 412, as well as along wall 402.

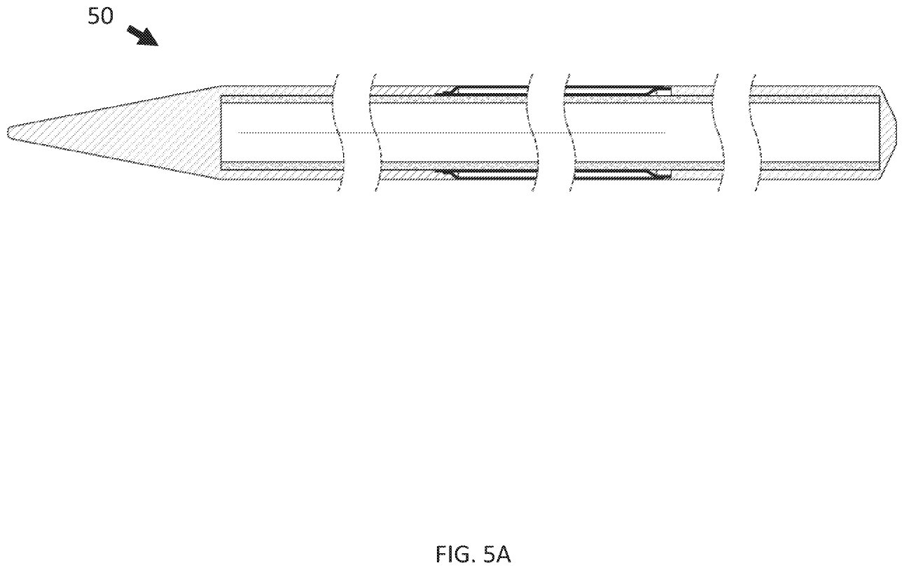

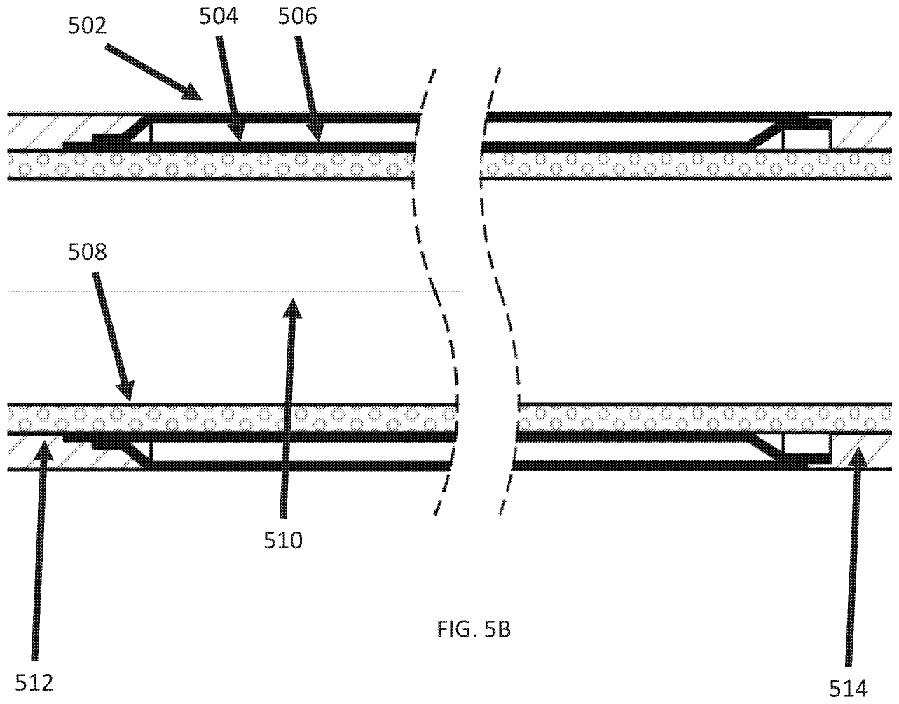

FIG. 5A provides a further embodiment of the disclosed components. FIG. 5B provides a close up of a cross-section of the component of FIG. 5A. As shown, a component can include a sealed space 506 (which space can be evacuated), which space can be defined between walls 502 and 504. The component can include outer wall portions 512 and 514, which portions can be joined to one or both of walls 502 and 504. Cavity 510 can be defined within the component. Wick 508 can be enclosed within the component; suitable wicks and their operation are described elsewhere herein. As shown in FIG. 5B, one of walls 502 and 504 can taper/flare toward the other wall at one location, and then the other of walls 502 and 504 can taper/flare toward the other wall at another location.

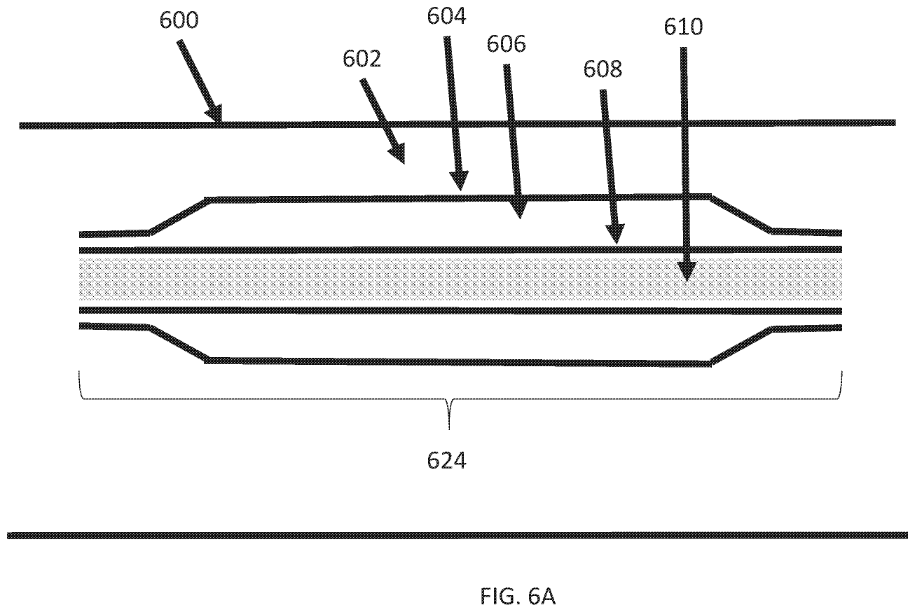

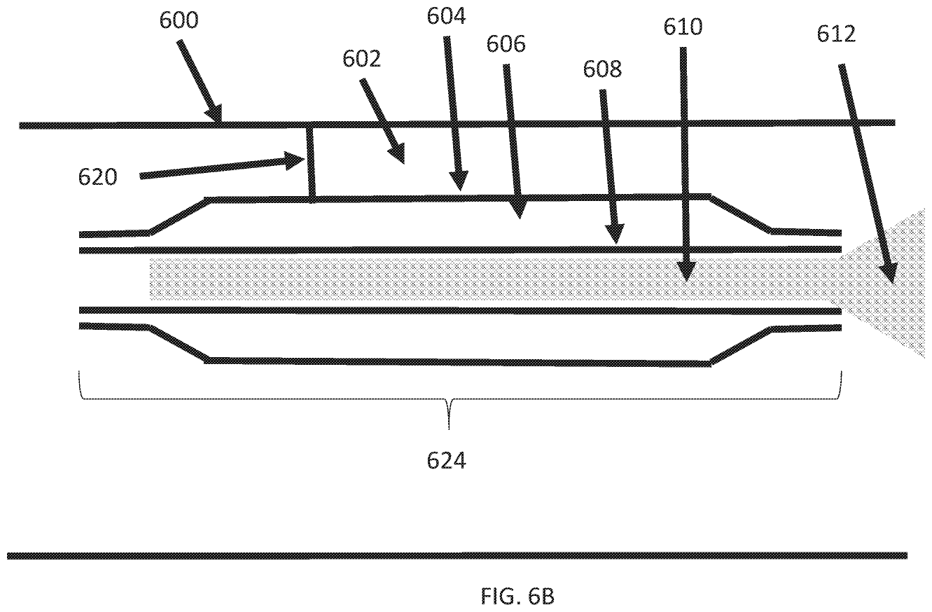

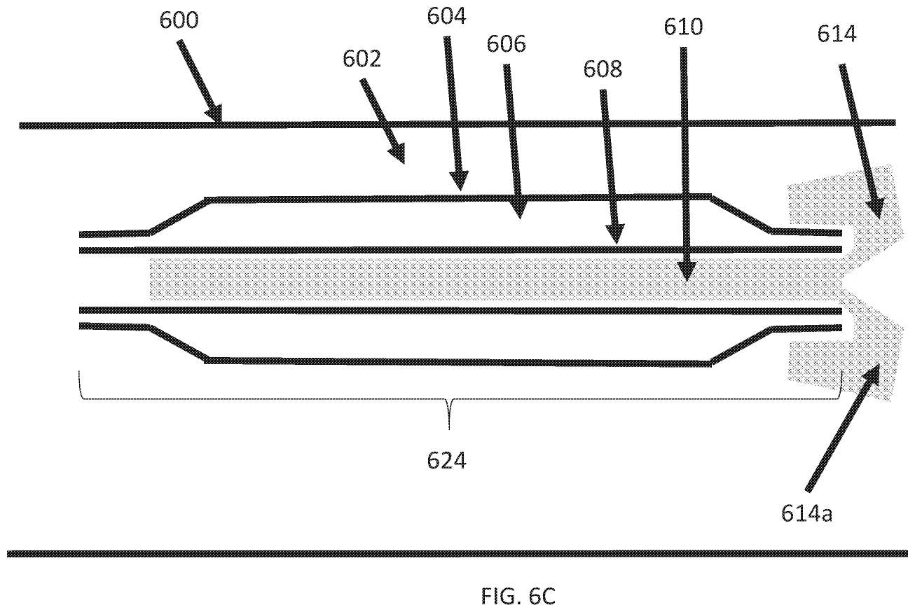

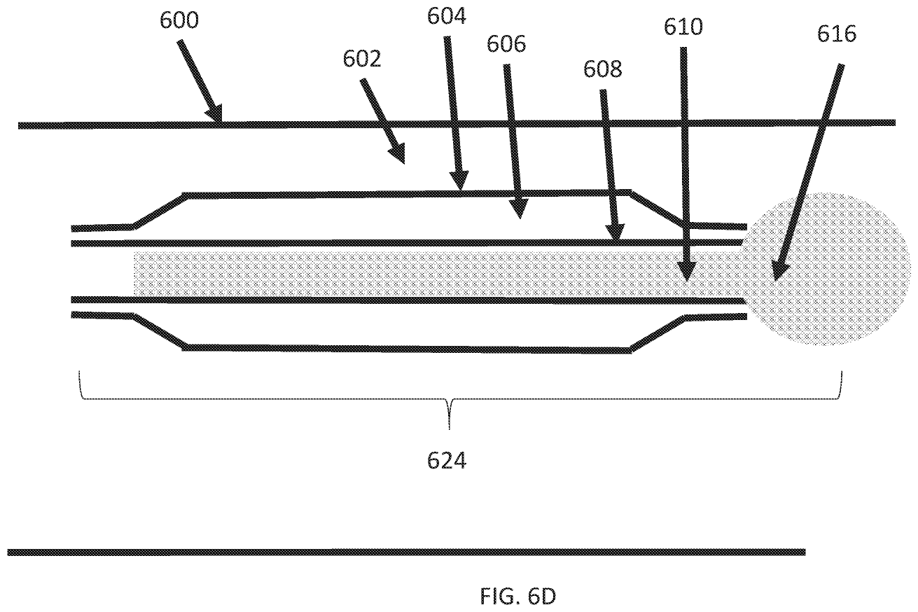

FIG. 6A provides a view of an alternative embodiment of the disclosed technology. As shown, wall 600 can enclose cavity 602. Within cavity 602 can be enclosed an assembly 624, which assembly can include walls 604 and 608, which walls define sealed, evacuated space 606 therebetween. Wick 610 can be enclosed within the assembly. Without being bound to any particular theory, fluid can be vaporized at the left hand side of the component, with the vapor being communicated (from left to right) along cavity 602, in the annular/tubular portion of cavity 602 that surrounds the assembly. The vapor can then condense on the right-hand end of wick 610 (not labeled), and the condensed vapor (now in liquid form) is communicated from right to left along wick 610. When the liquid reaches the left-hand-side of wick 610, the liquid is vaporized again. Feature 620 can be used to position the wick-containing assembly within wall 600. Feature 620 can be, without limitation, a bracket, a frame, a spring, or other features known in the art for positioning a component within another component.

Without being bound to any particular theory or embodiment, one or both walls of the assembly can flare outwards. As one example, one or both walls of the assembly can flare outwards at an end of the assembly that is pointed/directed toward the “hot end” of the component, i.e., the region of the component where the working fluid is vaporized by heat absorbed by the component. Again without being bound to any particular theory, such a flared/expanding geometry can promote expansion and cause additional cooling, e.g., via the Joule-Thomson effect.

FIG. 6B provides a view of an alternative embodiment of the disclosed technology. As shown, wall 600 can enclose cavity 602. Within cavity 602 can be enclosed an assembly 624, which assembly can include walls 604 and 608, which walls define sealed, evacuated space 606 therebetween. Wick 610 can be enclosed within the assembly. As shown, wick 610 can include a flared portion 612. Without being bound to any particular theory, the flared portion of wick 610 can provide for enhanced condensation of vapor onto that flared portion of the wick.

FIG. 6C provides a view of an alternative embodiment of the disclosed technology. As shown, wall 600 can enclose cavity 602. Within cavity 602 can be enclosed an assembly 624, which assembly can include walls 604 and 608, which walls define sealed, evacuated space 606 therebetween. Wick 610 can be enclosed within the assembly. As shown, wick 610 can include extension 614 and extension 614a. Without being bound to any particular theory, the extensions can provide for enhanced condensation of vapor onto that flared portion of the wick. As shown, an extension can extend beyond the walls that define space 606. In some embodiments, an extension can extend beyond and then back over a wall that defines space 606.

FIG. 6D provides a view of an alternative embodiment of the disclosed technology. As shown, wall 600 can enclose cavity 602. Within cavity 602 can be enclosed an assembly 624, which assembly can include walls 604 and 608, which walls define sealed, evacuated space 606 therebetween. Wick 610 can be enclosed within the assembly. As shown, wick 610 can include a flared portion 616, which can be shaped as a sphere or partial sphere. Without being bound to any particular theory, the flared portion of wick 610 can provide for enhanced condensation of vapor onto that flared portion of the wick.

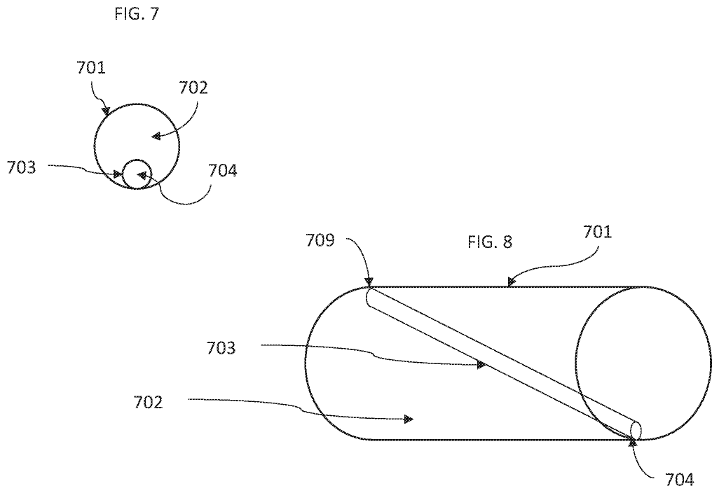

FIG. 7 provides an end-on view of a component according to the present disclosure. As shown, outer wall 701 defines cavity 702 therein. Assembly 703 is disposed within the cavity, with end 704 of assembly 703 being exposed to the environment exterior to the assembly.

FIG. 8 provides a cutaway view of a component according to FIG. 7. As shown, assembly 703 is disposed within cavity 702, and includes first end 704 and second end 709. As shown, assembly 703 need not be coaxial with cavity 702.

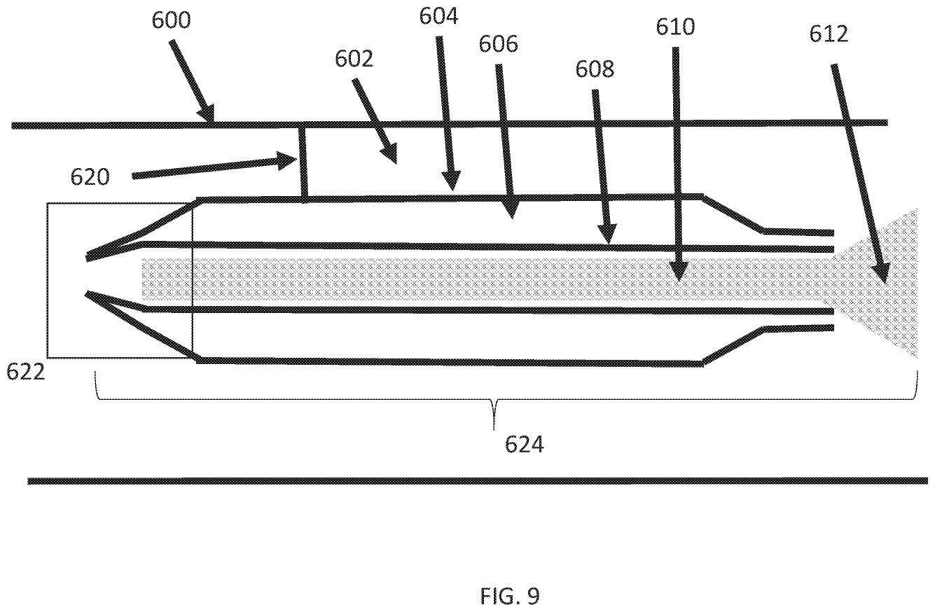

FIG. 9 provides a view of an alternative embodiment of the disclosed technology. As shown, wall 600 can enclose cavity 602. Within cavity 602 can be enclosed an assembly 624, which assembly can include walls 604 and 608, which walls define sealed, evacuated space 606 therebetween. Wick 610 can be enclosed within the assembly. As shown, wick 610 can include a flared portion 612. Without being bound to any particular theory, the flared portion of wick 610 can provide for enhanced condensation of vapor onto that flared portion of the wick. As shown in FIG. 9, assembly 624 can include a tapered (narrowed) region 622, which region can function as a nozzle that encourages transport of fluid along wick 610.

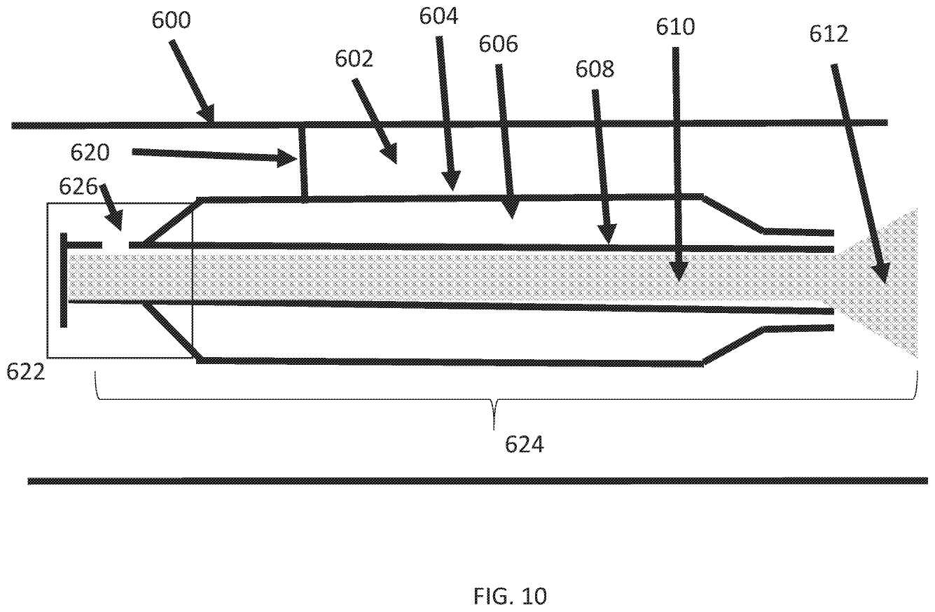

FIG. 10 provides a view of an alternative embodiment of the disclosed technology. As shown, wall 600 can enclose cavity 602. Within cavity 602 can be enclosed an assembly 624, which assembly can include walls 604 and 608, which walls define sealed, evacuated space 606 therebetween. Wick 610 can be enclosed within the assembly. As shown, wick 610 can include a flared portion 612. Without being bound to any particular theory, the flared portion of wick 610 can provide for enhanced condensation of vapor onto that flared portion of the wick. As shown in FIG. 9, assembly 624 can include a nozzle region 622, which region can include a slit 626 that functions as a nozzle that encourages transport of fluid along wick 610. The wick can be optionally contained in a closed-ended container defined by wall 608, though this is not a requirement. Without being bound by any theory, a slit can encourage a Venturi effect fluid flow.

### Embodiments

The following embodiments are illustrative only and do not limit the present disclosure or the appended claims.

Embodiment 1. A heat transfer component, comprising: a sealed enclosure, the sealed enclosure having within a cavity having a first part, a second part, and a third part, the first part of the cavity being configured to receive heat from a heat source and the third part of the cavity being configured to deliver heat received from the heat source; a fluid disposed within the cavity; a wick disposed within the enclosure, the wick being in fluid communication with the fluid and also with at least the first part of the cavity and the third part of the cavity of the cavity, and the wick being capable of transporting fluid (a) between the first part of the cavity and the third part of the cavity, (b) between the third part of the cavity and the first part of the cavity, or both (a) and (b); and a first sealed evacuated space defined between two walls disposed between the second part of the cavity and the environment exterior to the heat transfer component.

The enclosure can comprise metals, ceramics, or any combination thereof. Without being bound to any particular theory, the first part of the cavity can be where fluid is vaporized by heat absorbed by the component, and the third part of the cavity can be where fluid condenses onto wick material.

A wick material is suitable a material that supports capillary action transport of fluid. Materials formed by way of sintered-together particles are considered suitable. Porous materials, e.g., polymers, ceramics, metals (including alloys), metalloids, and the like, are also considered suitable.

Suitable fluids (which can be termed “working fluids” in some embodiments) can be chosen according to the temperatures at which the heat transfer component may operate. Some non-limiting examples include, e.g., liquid helium for comparatively low temperature applications (2-4 K), mercury (523-923 K), sodium (873-1473 K) and even indium (2000-3000 K) for comparatively high temperatures. Heat transfer components can use ammonia (213-373 K), alcohol (methanol (283-403 K) or ethanol (273-403 K)) or water (298-573 K) as the working fluid. The foregoing list is exemplary only, as other working fluids can be used. A user can select their own working fluid, depending on the user's needs.

Embodiment 2. The heat transfer component of Embodiment 1, wherein the cavity defines an aspect ratio of from about 10,000:1 to about 1:1. The aspect ratio of the cavity can be, e.g., from about 10,000:1 to about 1:1, or from about 5,000:1 to about 1:1, from about 1,000:1 to about 1:1, from about 500:1 to about 1:1, from about 250:1 to about 1:1, from about 100:1 to about 1:1, from about 50:1 to about 1:1, from about 20:1 to about 1:1, from about 10:1 to about 1:1, from about 5:1 to about 1:1, or even from about 2:1 to about 1:1.

Embodiment 3. The heat transfer component of any of Embodiments 1-2, wherein the first sealed evacuated space is characterized as annular.

Embodiment 4. The heat transfer component of any one of Embodiments 1-3, wherein at least one of the sealed enclosure and the cavity is characterized as elongate. Tubular or cylindrical enclosures and cavities are considered especially suitable. Cavities and enclosures can be coaxial with one another, but this is not a requirement.

Embodiment 5. The heat transfer component of any one of Embodiments 1-4, wherein at least one of the sealed enclosure and the cavity is characterized as serpentine. The enclosure and/or cavity can have one or more curves, corners, or bends.

Embodiment 6. The heat transfer component of any one of Embodiments 1-5, wherein the wick is characterized as tubular in configuration.

Embodiment 7. The heat transfer component of any one of Embodiments 1-6, wherein the wick is characterized as columnar (e.g., rod-shaped) in configuration. A wick can include one, two, three, or more materials. A wick can also include one, two, or more segments in fluid communication with one another.

Embodiment 8. The heat transfer component of any one of Embodiments 1-7, further comprising an assembly that comprises a second sealed evacuated space defined between two walls, the second sealed evacuated space being disposed between the wick and the second part of the cavity.

Embodiment 9. The heat transfer component of Embodiment 8, wherein the wick is in fluid communication with the second sealed evacuated space.

Embodiment 10. The heat transfer component of Embodiment 8, wherein the wick is at least partially enclosed within the second sealed evacuated space. FIG. 6A provides a non-limiting examples of such an enclosure; in that figure, the wick is enclosed within the assembly 624.

Embodiment 11. The heat transfer component of Embodiment 10, wherein the wick extends beyond at least one wall that defines the second sealed evacuated space.

Embodiment 12. The heat transfer component of any of Embodiments 8-11, wherein the assembly is secured in position within the enclosure. The assembly can be secured with, e.g., a hangar, a bracket, or other component.

Embodiment 13. The heat transfer component of any of Embodiments 8-12, wherein the assembly comprises at least one mounting feature. Exemplary mounting features include, e.g., hangars, brackets, tabs, slots, grooves, slots, and the like.

Embodiment 14. The heat transfer component of any of Embodiments 1-13, wherein the enclosure comprises at least one mounting feature.

Embodiment 15. The heat transfer component of any of Embodiments 1-14, wherein the enclosure comprises a nozzle. Nozzles can be formed by way of a narrowing cross-section, a slit, or other outlet.

Embodiment 16. The heat transfer component of any of Embodiments 8-14, wherein the assembly comprises a nozzle.

Embodiment 17. The heat transfer component of any of Embodiments 8-14, wherein the assembly defines a non-uniform cross-section along a length of the assembly.

Embodiment 18. The heat transfer component of Embodiment 8, wherein the second sealed evacuated space is characterized as annular.

Embodiment 19. A method, comprising: with a heat transfer component according to any one of Embodiments 1-18, transferring with the heat transfer component heat that is received from a heat source.

Embodiment 20. A method, comprising with a heat transfer component according to any one of Embodiments 1-18, exposing the heat component to heat from a heat source so as to vaporize fluid within the first part of the cavity, to effect condensation of the fluid within the third part of the cavity, and to effect transport of the condensed fluid along the wick from the third part of the cavity to the first part of the cavity.

Embodiment 21. A heat transfer component, comprising: a tubular enclosure, the tubular enclosure having within a sealed annular cavity, the sealed annular cavity having a first part, a second part, and a third part; a fluid disposed within the sealed annular cavity; and a wick disposed within the sealed annular cavity, the wick being in fluid communication with the fluid and the wick being capable of transporting fluid (a) between the first part of the cavity and the third part of the cavity, (b) between the third part of the cavity and the second part of the cavity, or both (a) and (b); and a first sealed evacuated space disposed between the second part of the cavity and the environment exterior to the heat transfer component.

Embodiment 22. The heat transfer component of Embodiment 21, wherein the wick is characterized as tubular. As described elsewhere herein, a wick can be rod-shaped.

Embodiment 23. The heat transfer component of any one of Embodiments 21-22, wherein the sealed annular cavity extends about less than the circumference of the tubular enclosure. As an example, the cavity can extend about 180 degrees of the circumference of the tubular enclosure.

Embodiment 24. The heat transfer component of any one of Embodiments 21-23, wherein the enclosure is characterized as serpentine.

Embodiment 25. The heat transfer component of any one of Embodiments 21-24, wherein the enclosure defines an aspect ratio of from about 10,000:1 to about 1:1.

Embodiment 26. A method, comprising: with a heat transfer component according to any one of Embodiments 21-25, transferring with the heat transfer component heat that is received from a heat source.

Embodiment 27. A method, comprising with a heat transfer component according to any one of Embodiments 21-26, exposing the heat component to heat from a heat source so as to vaporize fluid within the first part of the cavity, to effect condensation of the fluid within the third part of the cavity, and to effect transport of the condensed fluid along the wick from the third part of the cavity to the first part of the cavity.

Embodiment 28. A heat transfer component, comprising: a sealed enclosure, the sealed enclosure having within a cavity having a first part, a second part, and a third part, the first part of the cavity being configured to receive heat from a heat source and the third part of the cavity being configured to deliver heat received from the heat source; a fluid disposed within the cavity; further comprising an assembly that comprises a second sealed evacuated space defined between two walls, the second sealed evacuated space being disposed between the wick and the second part of the cavity, the component being configured so as to define a space between a wall of the assembly and the sealed enclosure, the space optionally being annular in shape.

As shown in the attached FIGs., wick material can be disposed about the interior of a wall that defines an enclosure of the disclosed components. Wick material can also be disposed within an assembly that itself defines a sealed, evacuated space between two walls, e.g., in FIG. 6A. In such an embodiment, the wick can be disposed such that it is enclosed by the sealed, evacuated space. The wick material can be present in tube form, but this is not a requirement, as the wick material can be present as a column, rod, or in other form.

Wick material can (e.g., FIG. 6B, 6C) extend beyond a wall that forms a sealed evacuated space that encloses the wick. Wick material can be affixed (e.g., via adhesive, brazing, sintering, or other methods) to a wall. Wick material can be disposed so as to wrap around (or even wrap back around) a wall, e.g., FIG. 6C.

By reference to non-limiting FIG. 6A, an end of wall 604 can extend beyond an end of wall 608. (Alternatively, an end of wall 608 can extend beyond an end of wall 604.) The extending wall end can be coated (inside, outside, or both) with wick material to facilitate condensing of the heat transfer fluid. By reference to non-limiting FIG. 6B, a portion (e.g., flare 612) of wick 608 can extend beyond one or both ends of walls 604 and 608.

Without being bound to any particular theory or embodiment, wick 604 can extend beyond the one or both ends of walls 604 and 608 so as to extend into a region of the component where vapor condenses onto the wick. Also without being bound to any particular theory or embodiment, wick 604 can extend beyond the one or both ends of walls 604 and 608 so as to extend into a region of the component where fluid is vaporized by way of heat absorbed by the heat transfer component from a heat source.

A component according to the present disclosure can also include one or more features that are incorporated into the exterior (e.g., wall 604 of FIG. 6A) of the assembly. Such features can be used to position the assembly (and/or maintain the assembly in position) within the component. Example features include, e.g., brackets, frames, grooves, ridges, tabs, slots, hangars, and the like. Likewise, a component according to the present disclosure can include one or more features that are incorporated into the interior of the enclosure for positioning or maintaining in position a sub-component (e.g., wick, assembly comprising evacuated space and wick) of the assembly. The component can also include one or more features incorporated into the exterior of the component to position the assembly or maintain the assembly in position.

Without being bound to any particular theory, a heat transfer component can operate by utilizing thermal conductivity and phase transition to effectively transfer heat between two solid interfaces. At the hot interface of a heat pipe a liquid in contact with a thermally conductive solid surface turns into a vapor by absorbing heat from that surface. The vapor then travels along the heat pipe to the cold interface and condenses back into a liquid—releasing the latent heat. The liquid then returns to the hot interface through either capillary action, centrifugal force, or gravity, and the cycle repeats.

Without being bound to any particular theory, phase change of the thermal transfer solution can be effected so as to occur (or begin to occur) inside the thermal insulation covering the wick. This can cause the thermal transfer solution to expand and helps to force the solution from the thermal insulation space.

In some embodiments, an end of a thermal insulation covering the wick can be tapered, e.g., to form a nozzle. Such a taper can be formed by pinching towards one another one or both walls that define the sealed evacuated space of such insulation, e.g., tapered region 622 of assembly 624 in FIG. 9. Alternatively, a nozzle can be formed by an end of one of the walls that defines the sealed evacuated space extending beyond the end of the other of the walls. A nozzle can also be formed by forming a slit in a wall that contains wick material and closing off an end of the tube. Without being bound by any particular theory, the presence of a slit can support a Venturi-type fluid flow than encourages fluid transport within the wick. Also without being bound to any particular theory, a nozzle (including slits) can act to spray the working fluid into the “hot end” of the component, i.e., the region of the component where the working fluid is vaporized by heat absorbed by the component.

1. A heat transfer component, comprising:
a sealed enclosure, the sealed enclosure having within a cavity having a first part, a second part, and a third part, the first part of the cavity being configured to receive heat from a heat source and the third part of the cavity being configured to deliver heat received from the heat source;
a fluid disposed within the cavity;
a wick disposed within the enclosure, the wick being in fluid communication with the fluid and also with at least the first part of the cavity and the third part of the cavity of the cavity, and the wick being capable of transporting fluid (a) between the first part of the cavity and the third part of the cavity, (b) between the third part of the cavity and the first part of the cavity, or both (a) and (b); and
a first sealed evacuated space defined between two walls disposed between the second part of the cavity and the environment exterior to the heat transfer component.

2. The heat transfer component of claim 1, wherein the cavity defines an aspect ratio of from about 10,000:1 to about 1:1.

3. The heat transfer component of claim 1, wherein the first sealed evacuated space is characterized as annular.

4. The heat transfer component of claim 1, wherein at least one of the sealed enclosure and the cavity is characterized as elongate.

5. The heat transfer component of claim 1, wherein at least one of the sealed enclosure and the cavity is characterized as serpentine.

6. The heat transfer component of claim 1, wherein the wick is characterized as tubular in configuration.

7. The heat transfer component of claim 1, wherein the wick is characterized as columnar in configuration.

8. The heat transfer component of claim 1, further comprising an assembly that comprises a second sealed evacuated space defined between two walls, the second sealed evacuated space being disposed between the wick and the second part of the cavity.

9. The heat transfer component 8, wherein the wick is in fluid communication with the second sealed evacuated space.

10. The heat transfer component of claim 8, wherein the wick is at least partially enclosed within the second sealed evacuated space.

11. The heat transfer component of claim 10, wherein the wick extends beyond at least one wall that defines the second sealed evacuated space.

12. The heat transfer component of claim 8, wherein the assembly is secured in position within the enclosure.

13. The heat transfer component of claim 8, wherein the assembly comprises at least one mounting feature.

14. The heat transfer component of claim 1, wherein the enclosure comprises at least one mounting feature.

15. The heat transfer component of claim 1, wherein the enclosure comprises a nozzle.

16. The heat transfer component of claim 8, wherein the assembly comprises a nozzle.

17. The heat transfer component of claim 8, wherein the assembly defines a non-uniform cross-section along a length of the assembly.

18. The heat transfer component of claim 8, wherein the second sealed evacuated space is characterized as annular.

19. A method, comprising: with a heat transfer component according to claim 1, transferring with the heat transfer component heat that is received from a heat source.

20. A method, comprising with a heat transfer component according to claim 1, exposing the heat component to heat from a heat source so as to vaporize fluid within the first part of the cavity, to effect condensation of the fluid within the third part of the cavity, and to effect transport of the condensed fluid along the wick from the third part of the cavity to the first part of the cavity.

21. A heat transfer component, comprising:
a tubular enclosure, the tubular enclosure having within a sealed annular cavity, the sealed annular cavity having a first part, a second part, and a third part;
a fluid disposed within the sealed annular cavity; and
a wick disposed within the sealed annular cavity, the wick being in fluid communication with the fluid and the wick being capable of transporting fluid (a) between the first part of the cavity and the third part of the cavity, (b) between the third part of the cavity and the second part of the cavity, or both (a) and (b); and
a first sealed evacuated space disposed between the second part of the cavity and the environment exterior to the heat transfer component.

22. The heat transfer component of claim 21, wherein the wick is characterized as tubular.

23. The heat transfer component of claim 21, wherein the sealed annular cavity extends about less than the circumference of the tubular enclosure.

24. The heat transfer component of claim 21, wherein the enclosure is characterized as serpentine.

25. The heat transfer component of claim 21, wherein the enclosure defines an aspect ratio of from about 10,000:1 to about 1:1.

26. A method, comprising: with a heat transfer component according to claim 21, transferring with the heat transfer component heat that is received from a heat source.

27. A method, comprising with a heat transfer component according to claim 21, exposing the heat component to heat from a heat source so as to vaporize fluid within the first part of the cavity, to effect condensation of the fluid within the third part of the cavity, and to effect transport of the condensed fluid along the wick from the third part of the cavity to the first part of the cavity.

28. A heat transfer component, comprising:
a sealed enclosure, the sealed enclosure having within a cavity having a first part, a second part, and a third part,
the first part of the cavity being configured to receive heat from a heat source and the third part of the cavity being configured to deliver heat received from the heat source;
a fluid disposed within the cavity;
further comprising an assembly that comprises a second sealed evacuated space defined between two walls, the second sealed evacuated space being disposed between the wick and the second part of the cavity,
the component being configured so as to define a space between a wall of the assembly and the sealed enclosure, the space optionally being annular in shape.
